(19) United States
(12) Patent Application Publication
(10) Pub. No.: US 2015/0227454 A1
(43) Pub. Date: Aug. 13, 2015

(54) USER DEVICE AND DATA SWAP CONTROL METHOD THEREOF

(71) Applicant: Samsung Electronics Co., Ltd., Suwon-Si (KR)

(72) Inventors: Jae-Bum LEE, Gwangmyeong-si (KR); Sung-Hoon LEE, Seoul (KR); SeokHeon LEE, Suwon-si (KR)

(21) Appl. No.: 14/607,334

(22) Filed: Jan. 28, 2015

(30) Foreign Application Priority Data
Feb. 11, 2014 (KR) 10-2014-0015635

(51) Int. Cl. G06F 12/02; G11C 7/10

(52) U.S. Cl. CPC G06F 12/023; G11C 7/1072; G06F 2212/1044

(57) ABSTRACT

A user device includes an embedded memory to store application programs and user data, an application block to execute the application programs and to comprise a data swap module to manage a data swap function, and a dynamic random access memory (DRAM) configured to temporarily store driving data of an application program executed by the application block. The data swap module may determine whether an external memory is connected and select the external memory as a data swap memory where the driving data stored in the DRAM is to be swapped according to a result of the determination.

### CROSS-REFERENCE TO RELATED APPLICATIONS

This U.S. non-provisional patent application claims priority under 35 USC §119 to Korean Patent Application No. 10-2014-0015635, filed on Feb. 11, 2014, the entirety of which is hereby incorporated by reference.

### BACKGROUND

1. Technical Field

At least some example embodiments of the inventive concepts relate to a user device having a data swap function and a data swap control method thereof.

2. Description of the Related Art

An operating system (OS) overcomes a limitation of capacity of a main memory by using a virtual memory. The virtual memory is one type of memory management technique and is devised for a kernel that performs multiple operations. A computer data storage is virtualized as one memory space to appear as a practical directly-accessible main memory device, thereby a larger virtual memory space may be ensured. For achieving this, the OS uses a hard disk drive (HDD) as a swap memory. That is, when a spare space of a main memory is insufficient, some data in the main memory is swapped to the HDD. A swap space means a specific portion of a storage used for memory extension in an operating system (OS) supporting a virtual memory system. When a practically allocable memory is insufficient while a specific program requires a memory, some of data currently loaded to a dynamic random access memory (DRAM) is selected and moved to a swap space.

### SUMMARY

At least some example embodiments of the inventive concepts provide a user device having a data swap scheme and a data swap control method of the user device.

According to at least some example embodiments of the inventive concepts, a user device may include an embedded memory configured to store application programs and user data; an application block configured to execute the application programs, the application block including a data swap module configured to manage a data swap function; and a dynamic random access memory (DRAM) configured to temporarily store driving data of an application program executed by the application block, wherein the data swap module is configured to determine whether an external memory is connected and select the external memory as a data swap memory where the driving data stored in the DRAM is to be swapped according to a result of the determination.

The data swap module may be configured such that, based on the data swap module determining that the external memory is connected to the user device, the data swap module selects the external memory as the data swap memory according to an external request.

The data swap module may be configured such that, based on the external memory being connected to the user device, the data swap module selects the external memory as the data swap memory depending on whether the external memory satisfies a condition of the data swap memory.

The data swap module may be configured to select the external memory as the data swap memory when the external memory satisfies the condition of the data swap memory, and the data swap module may be configured to select the embedded memory as the data swap memory when the external memory does not satisfy the condition of the data swap memory.

The data swap module may be configured to adjust a size of a data swap area of the data swap memory according to an external request.

The data swap module may be configured such that, based on the external memory being disconnected from the user device, the data swap module selects the embedded memory as the data swap memory according to an external request.

The user device as may further comprise the external memory, wherein the external memory includes a user data area to store the user data and a swap area for performing a data swap operation.

The data swap module may be configured to adjust a size of the swap area of the external memory according to an external request.

According to at least some example embodiments of the inventive concepts, a mobile device may include a mobile communication block configured to provide a wireless communication function; an application block configured to provide user application together with the mobile communication block; a near field communication (NFC) antenna matching network system configured to transmit and receive NFC signals by inductive coupling; an NFC transceiver controlled by the application block, and configured to provide NFC signals to the NFC antenna matching network system and receive NFC signals from the NFC antenna matching network system; a display module configured to display an image in response to display signals received from the application block; an embedded memory configured to store application programs and user data to be used by the application block; and a dynamic random access memory (DRAM) configured to temporarily store driving data of an application program executed by the application block, wherein the application block includes a data swap module configured to manage a data swap function, and wherein the data swap module is configured to determine whether an external memory is connected and select the external memory as a data swap memory where the driving data stored in the DRAM is to be swapped, depending on a result of the determination.

The data swap module may be configured such that, based on the data swap module determining that the external memory is connected to the user device, the data swap module selects the external memory as the data swap memory according to an external request.

The data swap module may be configured such that, based on the external memory being connected to the mobile device, the data swap module selects the external memory as the data swap memory depending on whether the external memory satisfies a condition of the data swap memory.

The data swap module may be configured to select the external memory as the data swap memory when the external memory satisfies the condition of the data swap memory, and the data swap module may be configured to select the embedded memory as the data swap memory when the external memory does not satisfy the condition of the data swap memory.

The data swap module may be configured to adjust a size of a data swap area of the data swap memory according to an external request.

The data swap module may be configured such that, based on the external memory being disconnected from the mobile device, the data swap module selects the embedded memory as the data swap memory according to an external request.

The mobile device may further include the external memory, wherein the external memory includes a user data area to store the user data and a swap area for data swap, and the data swap module is configured to adjust a size of the swap area of the external memory according to an external request.

According to at least some example embodiments of the inventive concepts, a user device includes an embedded memory configured to store application programs and user data; a main memory configured to temporarily store driving data of an application program executed by the application block, the main memory being a random access memory (RAM); and an application block configured to execute the application programs, the application block including a data swap module configured to manage a data swap function, the data swap function including allocating a portion of a data swap memory as an extension of the main memory; wherein the data swap module is configured to execute the data swap function by selecting, based on selection criteria, between setting an external memory as the data swap memory and setting the embedded memory as the data swap memory.

The main memory may be a dynamic RAM (DRAM).

The data swap module may be configured to execute the data swap function by determining whether or not the external memory is connected to the user device, and selecting, as the data swap memory, one of the embedded memory and the external memory, based on the determination.

The data swap module may be configured such that, based on the external memory being connected to the user device, the data swap module selects the external memory as the data swap memory based on the selection criteria, and the data swap module may be configured such that, based on the external memory not being connected to the user device, the data swap module selects the embedded memory as the data swap memory.

The data swap module may be configured such that the selection criteria includes one or more of operating speed of the external memory, capacity of the external memory, and available space of the external memory.

### BRIEF DESCRIPTION OF THE DRAWINGS

The above and other features and advantages of example embodiments of the inventive concepts will become more apparent by describing in detail example embodiments of the inventive concepts with reference to the attached drawings. The accompanying drawings are intended to depict example embodiments of the inventive concepts and should not be interpreted to limit the intended scope of the claims. The accompanying drawings are not to be considered as drawn to scale unless explicitly noted.

FIG. 1 is a block diagram illustrating a configuration of a user device according to at least one example embodiment of the inventive concepts;

FIG. 2 is a data flow diagram illustrating a concept of data swap of a user device according to at least one example embodiment of the inventive concepts;

FIG. 3 is a flowchart illustrating a control method of a data swap module in a user device according to at least one example embodiment of the inventive concepts;

FIG. 4 is a flowchart illustrating a control method of a data swap module in a user device according to at least one example embodiment of the inventive concepts;

FIG. 5 is a flowchart illustrating a control method of a data swap module in a user device according to still at least one example embodiment of the inventive concepts;

FIG. 6 is a flowchart illustrating a control method of a data swap module in a user device according to yet at least one example embodiment of the inventive concepts; and

FIG. 7 is a block diagram illustrating a configuration of a user device according to at least one example embodiment of the inventive concepts.

### DETAILED DESCRIPTION

Detailed example embodiments of the inventive concepts are disclosed herein. However, specific structural and functional details disclosed herein are merely representative for purposes of describing example embodiments of the inventive concepts. Example embodiments of the inventive concepts may, however, be embodied in many alternate forms and should not be construed as limited to only the embodiments set forth herein.

Accordingly, while example embodiments of the inventive concepts are capable of various modifications and alternative forms, embodiments thereof are shown by way of example in the drawings and will herein be described in detail. It should be understood, however, that there is no intent to limit example embodiments of the inventive concepts to the particular forms disclosed, but to the contrary, example embodiments of the inventive concepts are to cover all modifications, equivalents, and alternatives falling within the scope of example embodiments of the inventive concepts. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the inventive concepts. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the inventive concepts. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

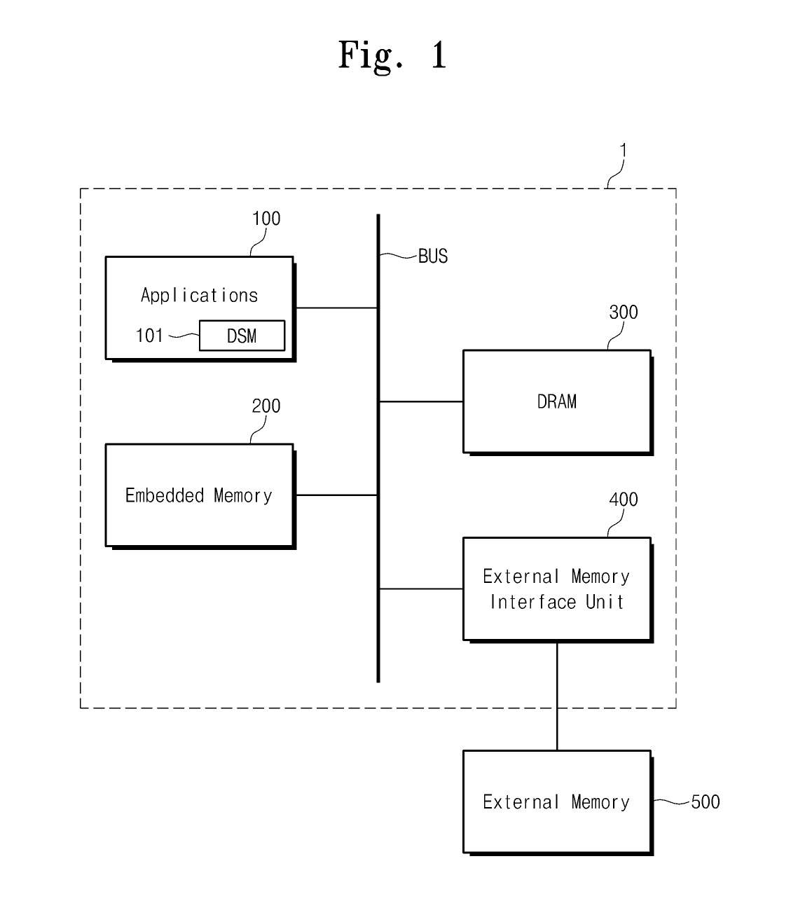

FIG. 1 is a block diagram illustrating a configuration of a user device 1 according to at least one example embodiment of the inventive concepts. The user device may be, for example an electronic device. The user device 1 may include an application block 100, an embedded memory 200, a DRAM 300, and an external memory interface unit 400. The application block 100, the embedded memory 200, the DRAM 300, and the external memory interface unit 400 may be connected to a bus. Although an example of directly connecting components of the user device 1 to the bus is shown in FIG. 1, some or all components of the user device 1 may be connected to the bus through interface units (not shown). Though the user device 1 will be explained herein with reference to an example where the user device 1 includes, as main memory, the DRAM 300, instead of, or in addition to the DRAM 300, the user device 1 may also include other types of memory devices as main memory. For example, other types of memory devices that may be included in the user device 1 as main memory include a static RAM (SRAM), a dynamic RAM (DRAM), a synchronous DRAM (SDRAM), phase-change RAM (PRAM), a resistive RAM (RRAM), magnetoresistive RAM (MRAM), or a ferroelectric RAM (FRAM).

According to at least some example embodiments of the inventive concepts, the application block 100 may include a processor. The term ‘processor’, as used herein, may refer to, for example, a hardware-implemented data processing device having circuitry that is physically structured to execute desired operations including, for example, operations represented as code and/or instructions included in a program. Examples of the above-referenced hardware-implemented data processing device include, but are not limited to, a microprocessor, a central processing unit (CPU), a processor core, a multiprocessor, an application-specific integrated circuit (ASIC), and a field programmable gate array (FPGA).

The application block 100 may be configured to control the overall operation of the user device 1. The application block 100 may be configured to drive various programs (e.g., application programs, a file system, device drivers, etc.). As will be explained in detail later, the application block 100 may include a data swap module 101 supporting a data swap function. According to at least some example embodiments, the data swap module 101 may be implemented by the application block 100. For example, the data swap module 101 may be implemented as software or firmware executed by the application block 100 and/or as a circuit within the application block 100. The embedded memory 200 may be used as a main storage and may include a nonvolatile memory. For example, the embedded memory 200 may include a NAND flash memory. Various types of data, for example, data required for a basic operation of a user device (e.g., bootloader, operating system (OS) image, application programs, etc.) and user data (e.g., game programs, etc.), may be stored in the embedded memory 200. The DRAM 300 may be used as a working memory. Data processed or required by the application block 100 may be loaded to the DRAM 300. The external memory interface unit 400 may provide connection of an external memory 500 to the user device 1. The external memory 500 may be used in accordance with needs of users.

The user device 1 may support a data swap function and may selectively use the embedded memory 200 and the external memory 500 as a data swap memory, where data swap memory is memory including a swap space which is used as an extension of the space of the DRAM 300. The data swap function may be selectively used under the control of the data swap module 101, which will be explained in detail later. Not only the embedded memory 200 but also the external memory 500 may be selectively used as a data swap memory to prevent the lifetime of the embedded memory 200 from decreasing due to supporting of the data swap function.

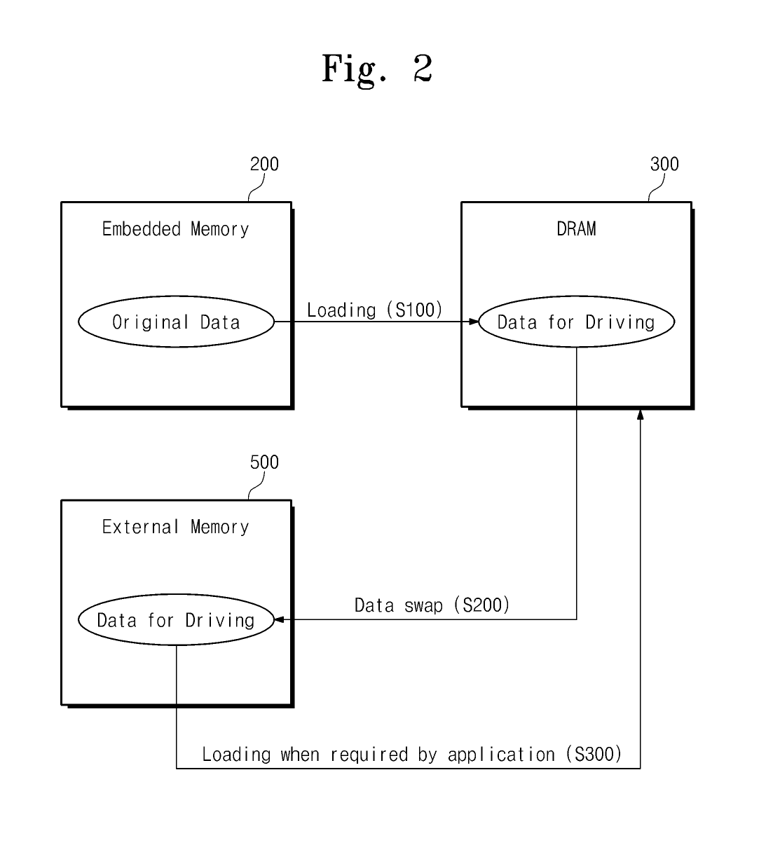

FIG. 2 is a data flow diagram illustrating a concept of data swap of a user device according to at least one example embodiment of the inventive concepts. In the example illustrated in FIG. 2, an external memory 500 is connected to a user device 1 through an external memory interface unit 400 and the external memory 500 is selected as a data swap memory under the control of a data swap module 101.

When an application program is executed, driving data, which is data required for executing/driving the application program, may be loaded from an embedded memory 200 to a DRAM 300 (S100), as is well-known in the art. Loading the data to the DRAM 300 requires operations of reading original data from the embedded memory 200, performing various operations (e.g., decompression, ECC encoding, etc.) to drive an application program, and loading resultant data to the DRAM 300. When the execution of the application program is terminated or data swap is required to ensure a memory space of the DRAM 300, data for driving loaded on the DRAM 300 may be stored in the external memory 500 under the control of the data swap module 101 (S200). The data swapped to the external memory 500 may be loaded to the DRAM 300, if necessary (S300). The data loaded to the DRAM 300 may be data loaded to the DRAM 300 that does not require various operations to drive the application program.

When a data swap operation is performed using the embedded memory 200, the lifetime of the embedded memory 200 may decrease due to repetition of a data write operation. In general, for some devices, the embedded memory 200 may not be replaceable. As the lifetime of the embedded memory 200 decreases, the lifetime of a device including the embedded memory 200 may also decrease. In addition, when swap data is a small amount of random data, performance degradation and lifetime reduction of a device may be accelerated due to increased number of fragmentations and frequent merge of the embedded memory 200.

In contrast, when data stored in the embedded memory 200 is used, execution performance of an application program may be enhanced by copying the data loaded to the DRAM 300 to the external memory 500, omitting a series of operations for loading original data (including, for example, operations of re-reading the original data from the embedded memory 200, performing operations to drive an application program, and loading resultant data to the DRAM 300) if a user executes the same application program, and immediately loading data previously stored in the external data 500 to the DRAM 300. Thus, a better environment may be provided to a user. Instead of the embedded memory 200, the external memory 500 may be used as a data swap memory to reduce a frequency in use of the embedded memory 200. An effect of increasing the lifetime of the device with the embedded memory 200 may be expected by decreasing the number of fragmentations of the embedded memory 200.

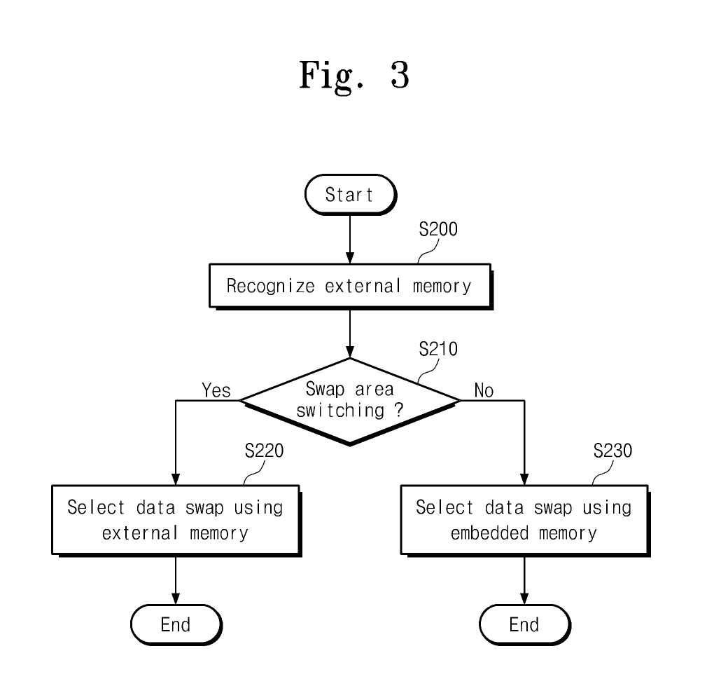

FIG. 3 is a flowchart illustrating a control method of a data swap module 101 in a user device 1 according to at least one example embodiment of the inventive concepts.

The user device 1 may selectively use one of an embedded memory 200 and an external memory 500 as a data swap memory by using the data swap module 101. A data swap memory used for data swap may be set to the internal memory 200 as a default state. Alternatively, the data swap memory used for data swap may be set to the external memory 500 as a default state. Alternatively, no particular memory may be set as the data swap memory in a default state. It will be appreciated that a default state is not limited to the default states described herein. For brevity of explanation, an example will be described in which the external memory 500 is connected to the user device 1 through an external memory interface unit 400 under the condition that the data swap memory used for data swap is set to the embedded memory 200 in a default state. According to the above example, a data swap control method of a user device according to at least one example embodiment of the inventive concepts will be described with reference to accompanying drawings.

When the external memory 500 is connected to the user device 1 through the external memory interface unit 400 by a user, the user device 1 may recognize the external memory 500 (S200). A data swap module 101 of the user device 1 may determine whether a swap area is to be switched or not (S210). For example, the data swap module 101 of the user device 1 may display a message asking the user whether the swap area needs to be switched or not. The message may be viewed by a user through a display (not shown) of the user device 1. If the swap area is switched by the user, data swap module 101 may select data swap using the external memory 500 (S220). In this case, a data swap operation may be performed using the external memory 500, as described with reference to FIG. 2. Afterwards, the flow may come to an end.

Meanwhile, when the swap area is not switched by the user, the data swap module 101 may select data swap using the embedded memory 200 (S230). That is, a data swap operation may be performed in a default state. In this case, when an application program is executed, data for executing/driving the application program may be loaded from the embedded memory 200 to a DRAM 300, the data for driving on the DRAM 300 may be stored in the embedded memory 200 under the control of the data swap module 101 when the execution of the application program is terminated or data swap is required to ensure a memory space of the DRAM 300, and the data for driving swapped to the embedded memory 200 may be reloaded to the DRAM 300, if necessary.

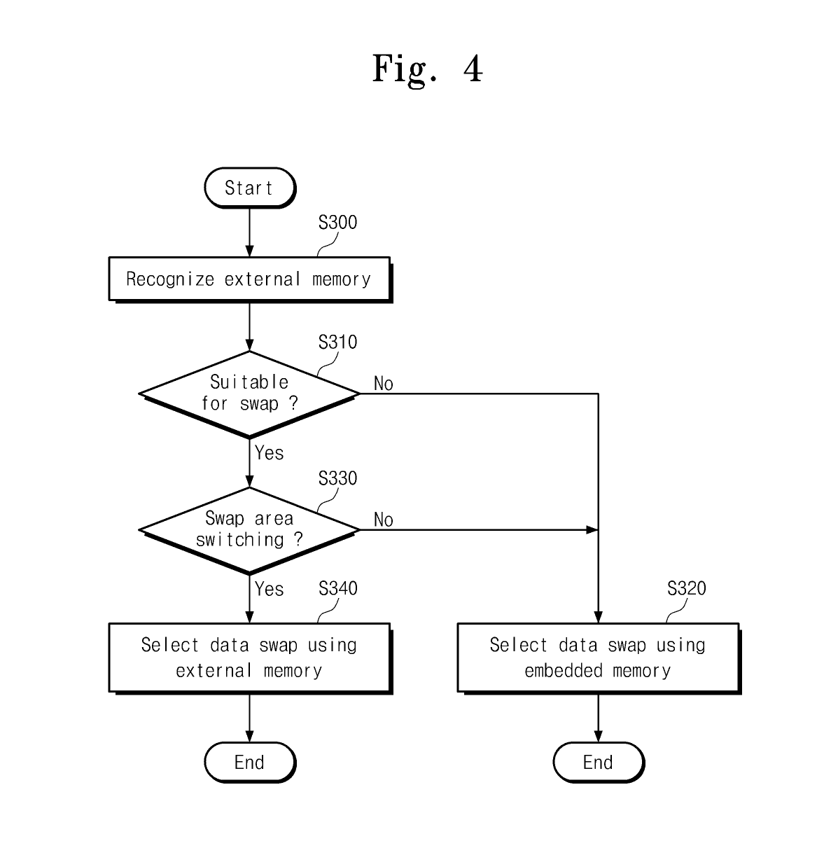

FIG. 4 is a flowchart illustrating a control method of a data swap module 101 in a user device 1 according to at least one example embodiment of the inventive concepts.

The user device 1 may selectively use one of an embedded memory 200 and an external memory 500 as a data swap memory by using the data swap module 101. The data swap memory used for data swap may be set to the embedded memory 200 as a default state. Alternatively, the data swap memory used for data swap may be set to the external memory 500 as a default state. Alternatively, no particular memory may be set as the data swap memory in a default state. It will be appreciated that a default state is not limited to the default states described herein. For brevity of explanation, an example will be explained in which the external memory 500 is connected to the user device 1 through an external memory interface unit 400 under the condition that a data swap memory used for data swap is set to the embedded memory 200 in a default state. Under the above assumption, a control method of a data swap module in a user device according to at least one example embodiment of the inventive concepts will be described with reference to accompanying drawings.

When the external memory 500 is connected to the user device 1 through the external memory interface unit 400, the user device 1 recognizes the external memory 500 (S300). When the external memory 500 is connected to the user device 1, the user device 1 may check various types of information with respect to the external memory 500 (e.g., operating speed, capacity, etc.) and may compare one or more of the various types of information to threshold values. Based on the checked various types of information, the data swap module 101 in the user device 1 may determine whether the external memory 500 is suitable for data swap (S310). For example, the comparison with the threshold values may indicate that one or more of the operating speed, capacity, an available space, and the like of the external memory 500 may not be suitable for performing a data swap operation. When it is determined that one or more of the operating speed, capacity, an available space, and the like of the external memory 500 are not suitable for performing a data swap operation, the flow proceeds to S320.

The data swap module 101 may select data swap using the embedded memory 200 (S320). That is, a data swap operation may be performed in a default state. In this case, when an application program is executed, data for executing/driving the application may be loaded from the embedded memory 200 to the DRAM 300, the data for driving on the DRAM 300 may be stored in the embedded memory 200 under the control of the data swap module 101 when the execution of the application program is terminated or data swap is required to ensure a memory space of the DRAM 300, and the data for driving swapped to the embedded memory 200 may be reloaded to the DRAM 300, if necessary.

If it is determined that the operating speed, capacity, an available space, and the like of the external memory 500 are suitable for performing a data swap operation, the flow proceeds to S330. The data swap module 101 in the user device 1 may determine whether a swap area is to be switched or not (S330). For example, the data swap module 101 in the user device 1 may ask a user whether the swap area needs to be switched or not. When the swap area is switched by the user, the data swap module 101 may select data swap using the embedded memory 500 (S340). In this case, the data swap operation may be performed using the external memory 500, as explained with reference to FIG. 2. Afterwards, the flow comes to an end.

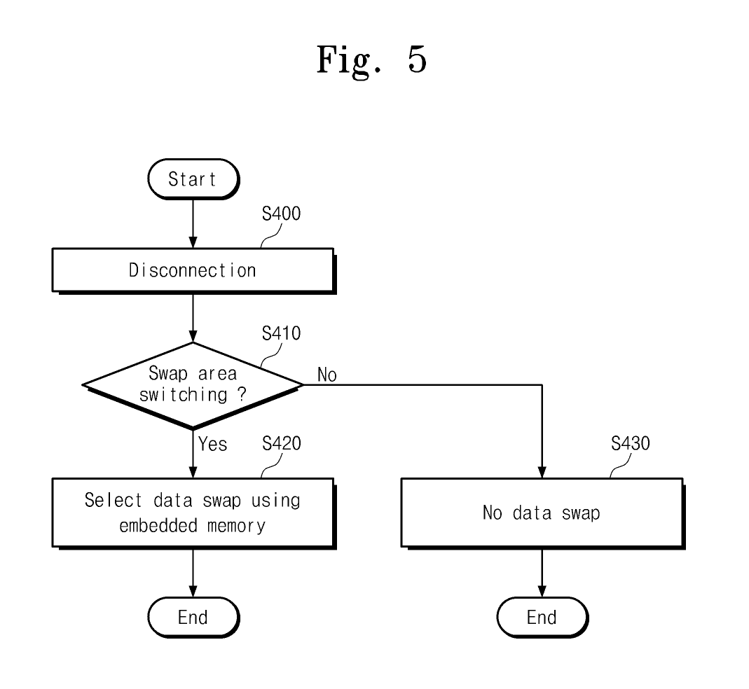

FIG. 5 is a flowchart illustrating a control method of a data swap module 101 in a user device 1 according to still at least one example embodiment of the inventive concepts.

It is assumed that an external memory 500 is used as a data swap memory according to the method described with reference to FIG. 3 or 4. Under the above assumption, a control method of the data swap module 101 in the user device 1 will now be described in detail with reference to accompanying drawings.

The external memory 500 may be disconnected from an external memory interface unit 400 of the user device 1 (S400). The data swap module 101 in the user device 1 may determine whether a swap area is to be switched or not (S410). For example, the data swap module 101 in the user device 1 may generate a message asking a user whether the swap area needs to be switched or not. The message may be viewed by the user through a display (not shown) of the user device 1 under the control of the data swap module 101. When the swap area is switched by the user, the data swap module 101 may select data swap using an embedded memory 200 (S420). Afterwards, the flow comes to an end. Meanwhile, when the swap area is not switched by the user, the flow proceeds to S430. The data swap module 101 in the user device 1 may select a state in which the data swap memory is not used (S430). In this case, the user device does not support a data swap function.

Although the external memory 500 is not connected to the user device 1, the data swap function of the user device 1 may be re-enabled by re-setting the internal memory 200 to a data swap memory according to the user's selection. This will be performed through the data swap module 101 as an application program. It will be appreciated that a manner of setting a data swap memory when the external memory 500 is disconnected from the user device 1 is not limited to that described above. For example, setting a data swap memory when the external memory 500 is disconnected from the user device 1 may be decided by considering a situation of the embedded memory 200, user's intension, and the like.

Data swap may compensate deficient capacity of the DRAM 300 to improve loading speed of an application program and data. Performance improvement with respect to application programs and data may be dependent on a size of a swap area. Hereinafter, a method of deciding a size of a swap area will be described in detail.

According to at least some example embodiments, the embedded memory 200 may be re-set to the data swap memory according to user's selection after a data swap function is disabled in a default state. For example, the data swap module 101 (or a corresponding application program) may be enabled to set the data swap function. Then, the data swap module 101 may determine whether there is the external memory 500 and select a data swap memory depending on a result of the determination to enable the data swap function. When there is no external memory 500, the embedded memory 200 is selected as a data swap memory. When there is the external memory 500, the external memory 500 or the embedded memory 200 may be selected as a data swap memory.

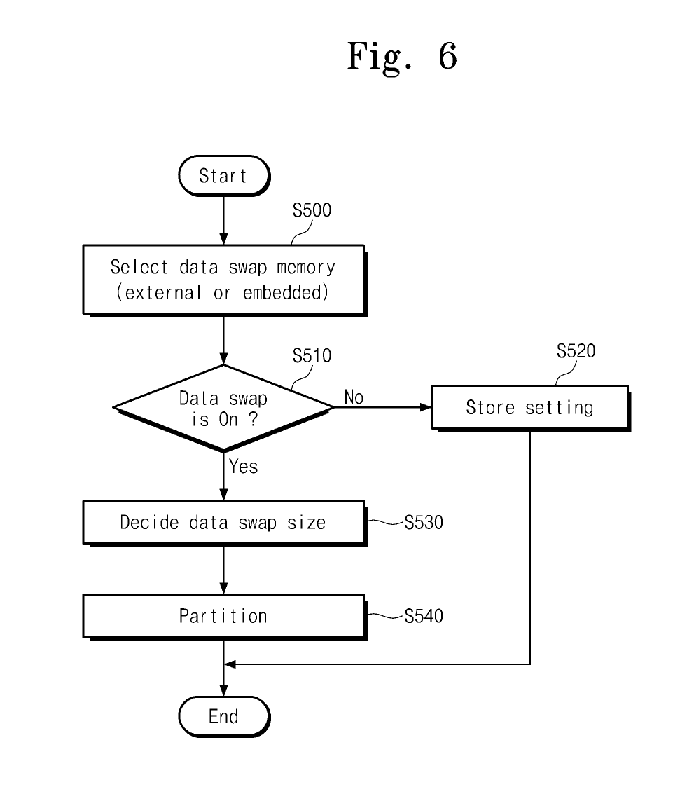

FIG. 6 is a flowchart illustrating a control method of a data swap module 101 in a user device 1 according to yet at least one example embodiment of the inventive concepts. The performance for application programs and data may vary depending on a size of a swap area of a data swap memory. A method of adjusting a size of a swap area by a user will be described with reference to accompanying drawings. A size of a swap area may be adjusted through the data swap module 101 in the user device 1 or through a separate application program.

A data swap memory may be selected (S500). One of an external memory 500 and an embedded memory 200 may be selected as the data swap memory. For brevity of description, an example will be described in which the external memory 500 is selected as the data swap memory. It is determined whether a data swap function is to be enabled or not (S510). For example, a screen to ask enabling or disabling of a data swap function is displayed through a display of the user device 1, and enabling or disabling of the data swap function may be selected by a user. When disabling of the data swap function is selected by the user, the flow proceeds to S520. Setting information of the user device 1 may be changed to set the data swap function, i.e., to disable the data swap function. Afterward, the flow may come to an end.

When enabling of the data swap function is selected by the user, the flow proceeds to S530. A size of a swap area may be decided (S530). For example, a screen to select the size of the swap area may be displayed through a display of the user device, and the size of the swap area may be selected by the user. A format operation (e.g., partition operation) may be performed on a data swap memory (e.g., an external memory 500) according to the changed setting (S540). Afterwards, the flow may come to an end. Data of the data swap memory that may be lost by the format operation may be backed up in advance by the user.

As described above, a size of a swap area of a data swap memory may be arbitrarily adjusted to support a data swap function for more application programs and data. Thus, performance of the user device 1 may be improved.

While an example of using the external memory 500 as a data swap memory has been explained, the embedded memory 200 may be used as a data swap memory. In this case, a size of a swap area of the embedded memory 200 may be arbitrarily adjusted in substantially the same fashion as explained above.

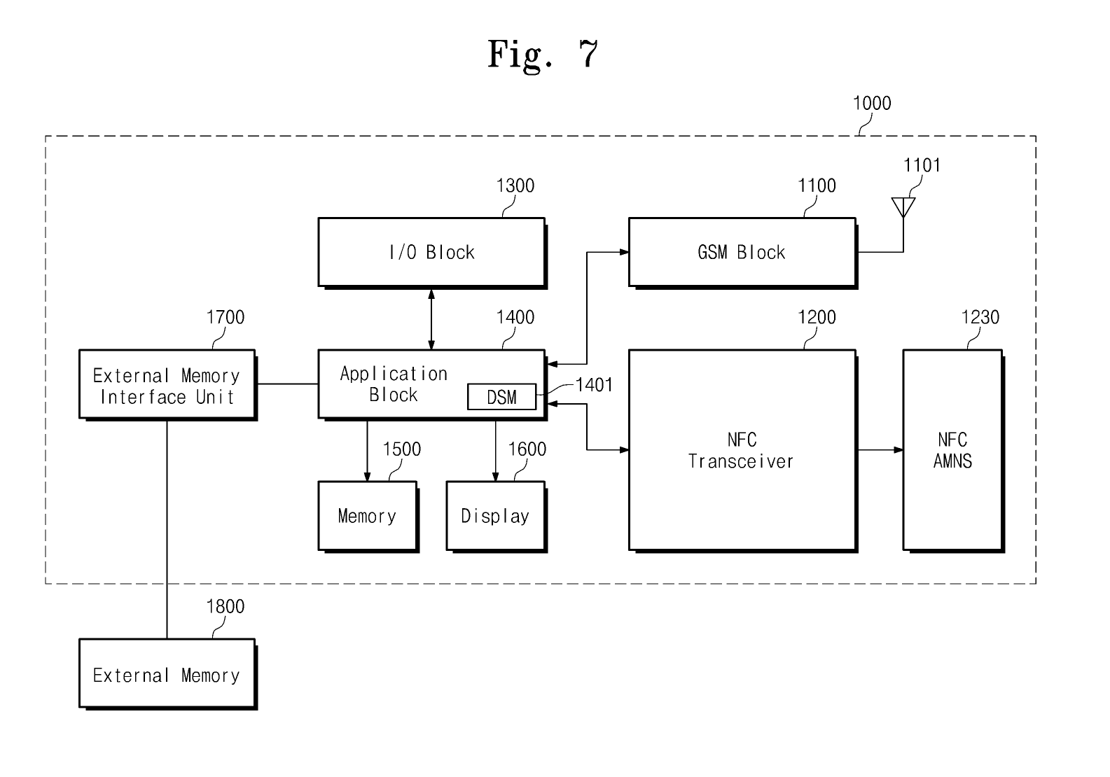

FIG. 7 is a block diagram illustrating a configuration of a user device according to at least one example embodiment of the inventive concepts. The user device shown in FIG. 7 may be a mobile phone (or smartphone). However, applications of at least some example embodiments of the inventive concepts are not limited to mobile phones.

Referring to FIG. 7, a mobile phone 1000 may include a global system for mobile communication (GSM) block 1100, a near field communication (NFC) transceiver 1200, an input/output (I/O) block 1300, an application block 1400, a memory 1500, and a display 1600. Components/blocks of the mobile phone 1000 in FIG. 7 are provided as examples. However, the mobile phone 1000 may include more or less components/blocks. Furthermore, although it is shown that a GSM technology is employed, the mobile phone 1000 may be implemented with other technologies such as code division multiple access 2000 (CDMA 2000), or long term evolution (LTE). The blocks in FIG. 7 may be implemented in integrated circuit (IC) form. Alternatively, some of the blocks may be implemented in IC form while the other blocks may be implemented in discrete form.

The GSM block 1100 may be connected to an antenna 1101, and may operate to provide wireless communication operations (e.g., a mobile phone calling) in a known way. The GSM block 1100 may include receiver and transmitter sections (not shown) internally to perform corresponding reception and transmission operations.

The NFC transceiver 1200 may be configured to transmit and receive NFC signals by inductive coupling for wireless communication. The NFC transceiver 1200 may provide the NFC signals to an NFC antenna matching network system 1230, and the NFC antenna matching network system 1230 may transmit the NFC signals through inductive coupling. The NFC antenna matching network system 1230 may receive NFC signals provided from another NFC device (not shown) and provide the received NFC signals to the NFC transceiver 1200.

The NFC transceiver 1200 may operate according to the specifications described in Near Field Communication Interface and Protocol-1 (NFCIP-1) and Near Field Communication Interface and Protocol-2 (NFCIP-2) and standardized in ECMA-340, ISO/IEC 18092, ETSI TS 102 190, ISO 21481, ECMA 352, ETSI TS 102 312, etc.

The application block 1400 may include hardware circuits (e.g., one or more processors) and operate to provide various user applications provided by the mobile phone 1000. The user applications may include voice call operations, data transmission, data swap, and the like. The application block 1400 may operate together with the GSM block 1100 to provide such features. The application block 1400 may have the same operations and/or structure as those described with respect to, for example, the application block 100 shown in FIG. 1. The application block 1400 may include a program for mobile point of sales (POS). Such program may provide credit card purchase and payment functions using a mobile phone, i.e., smartphone.

The display 1600 may display an image in response to display signals received from the application block 1400. The image may be generated by a camera (not shown) equipped on the mobile phone 1000. In addition, the image may be generated by the application block 1400. The display 1600 may internally include a memory (e.g., frame buffer) to temporarily store pixel values and may include a liquid crystal display (LCD) screen together with associated control circuits. The I/O block 1300 may provide an input function to the user and provide outputs to be received through the application block 1400.

The memory 1500 may store programs (commands) and/or data to be used by the application block 1400, and may be implemented with a RAM, a ROM, a flash memory or the like. The memory 1500 may include not only a volatile storage element but also a nonvolatile storage element.

According to at least one example embodiment, the memory 1500 includes a DRAM and an embedded memory. For example, the memory 1500 may have the same operations and/or structures as those described above with respect to both the embedded memory 200 and the DRAM 300 shown in FIG. 1.

Transmission and reception of NFC signal by the NFC transceiver 200 may be done in a time division fashion. Thus, a time interval in which the NFC transceiver 200 transmits NFC signals is referred to as a “transmission interval”, and a corresponding operation mode of the NFC transceiver 200 is regarded as a “transmission mode” or “NFC reader transmission mode”. Similarly, a time interval in which the NFC transceiver 200 receives NFC signals is referred to a “reception interval”, and a corresponding operation mode of the NFC transceiver 200 is regarded as a “reception mode” or “NFC reader reception mode”.

The mobile phone 1000 may further include an external memory interface unit 1700. The external memory 1800 may be connected to the mobile phone 1000 through the external memory interface unit 1700.

When the external memory 1800 is connected to the mobile phone 1000, a memory swap module 1401 of the application block 1400 may select the external memory 1800 as a data swap memory in the same or, alternatively, substantially the same fashion as that described above with reference to FIG. 3 or FIG. 4. The memory swap module 1401 of the application block 1400 may arbitrarily set to a size of a swap area of the external memory 1800 or the memory 1500 in substantially the same fashion as described with reference to FIG. 6. Thus, not only the memory 1500 but also the external memory 1800 may be selectively used as a data swap memory to prevent the lifetime of the embedded memory 1500 from decreasing due to supporting of a data swap function. To put it another way, the external memory 1800 may be replaced as necessary, thereby the lifetime of the mobile phone 1000 may be extended.

Example embodiments having thus been described, it will be obvious that the same may be varied in many ways. Such variations are not to be regarded as a departure from the intended spirit and scope of example embodiments of the inventive concepts, and all such modifications as would be obvious to one skilled in the art are intended to be included within the scope of the following claims.

What is claimed is:

1. A user device comprising:
an embedded memory configured to store application programs and user data;
an application block configured to execute the application programs, the application block including a data swap module configured to manage a data swap function; and
a dynamic random access memory (DRAM) configured to temporarily store driving data of an application program executed by the application block,
wherein the data swap module is configured to determine whether an external memory is connected and select the external memory as a data swap memory where the driving data stored in the DRAM is to be swapped according to a result of the determination.

2. The user device as set forth in claim 1, wherein the data swap module is configured such that, based on the data swap module determining that the external memory is connected to the user device, the data swap module selects the external memory as the data swap memory according to an external request.

3. The user device as set forth in claim 2, wherein the data swap module is configured such that, based on the external memory being connected to the user device, the data swap module selects the external memory as the data swap memory depending on whether the external memory satisfies a condition of the data swap memory.

4. The user device as set forth in claim 3, wherein the data swap module is configured to select the external memory as the data swap memory when the external memory satisfies the condition of the data swap memory, and
wherein the data swap module is configured to select the embedded memory as the data swap memory when the external memory does not satisfy the condition of the data swap memory.

5. The user device as set forth in claim 4, wherein the data swap module is configured to adjust a size of a data swap area of the data swap memory according to an external request.

6. The user device as set forth in claim 3, wherein the data swap module is configured such that, based on the external memory being disconnected from the user device, the data swap module selects the embedded memory as the data swap memory according to an external request.

7. The user device as set forth in claim 3, further comprising the external memory,
wherein the external memory includes a user data area to store the user data and a swap area for performing a data swap operation.

8. The user device as set forth in claim 7, wherein the data swap module is configured to adjust a size of the swap area of the external memory according to an external request.

9. A mobile device comprising:
a mobile communication block configured to provide a wireless communication function;
an application block configured to provide user application together with the mobile communication block;
a near field communication (NFC) antenna matching network system configured to transmit and receive NFC signals by inductive coupling;
an NFC transceiver controlled by the application block, and configured to provide NFC signals to the NFC antenna matching network system and receive NFC signals from the NFC antenna matching network system;
a display module configured to display an image in response to display signals received from the application block;
an embedded memory configured to store application programs and user data to be used by the application block; and
a dynamic random access memory (DRAM) configured to temporarily store driving data of an application program executed by the application block,
wherein the application block includes a data swap module configured to manage a data swap function, and
wherein the data swap module is configured to determine whether an external memory is connected and select the external memory as a data swap memory where the driving data stored in the DRAM is to be swapped, depending on a result of the determination.

10. The mobile device as set forth in claim 9, wherein the data swap module is configured such that, based on the data swap module determining that the external memory is connected to the mobile device, the data swap module selects the external memory as the data swap memory according to an external request.

11. The mobile device as set forth in claim 10, wherein the data swap module is configured such that, based on the external memory being connected to the mobile device, the data swap module selects the external memory as the data swap memory depending on whether the external memory satisfies a condition of the data swap memory.

12. The mobile device as set forth in claim 11, wherein the data swap module is configured to select the external memory as the data swap memory when the external memory satisfies the condition of the data swap memory, and
wherein the data swap module is configured to select the embedded memory as the data swap memory when the external memory does not satisfy the condition of the data swap memory.

13. The mobile device as set forth in claim 12, wherein the data swap module is configured to adjust a size of a data swap area of the data swap memory according to an external request.

14. The mobile device as set forth in claim 11, wherein the data swap module is configured such that, based on the external memory being disconnected from the mobile device, the data swap module selects the embedded memory as the data swap memory according to an external request.

15. The mobile device as set forth in claim 11, further comprising the external memory,
wherein the external memory includes a user data area to store the user data and a swap area for data swap, and
wherein the data swap module is configured to adjust a size of the swap area of the external memory according to an external request.

16. A user device comprising:
an embedded memory configured to store application programs and user data;
a main memory configured to temporarily store driving data of an application program executed by the application block, the main memory being a random access memory (RAM); and
an application block configured to execute the application programs, the application block including a data swap module configured to manage a data swap function, the data swap function including allocating a portion of a data swap memory as an extension of the main memory,
wherein the data swap module is configured to execute the data swap function by selecting, based on selection criteria, between setting an external memory as the data swap memory and setting the embedded memory as the data swap memory.

17. The user device of claim 16, wherein the main memory is a dynamic RAM (DRAM).

18. The user device of claim 16, wherein the data swap module is configured to execute the data swap function by,
determining whether or not the external memory is connected to the user device, and
selecting, as the data swap memory, one of the embedded memory and the external memory, based on the determination.

19. The user device of claim 18, wherein the data swap module is configured such that, based on the external memory being connected to the user device, the data swap module selects the external memory as the data swap memory based on the selection criteria, and
wherein the data swap module is configured such that, based on the external memory not being connected to the user device, the data swap module selects the embedded memory as the data swap memory.

20. The user device of claim 16, wherein the data swap module is configured such that the selection criteria includes one or more of operating speed of the external memory, capacity of the external memory, and available space of the external memory.
